(19) United States
(12) Patent Application Publication
(10) Pub. No.: US 2012/0293267 A1
(43) Pub. Date: Nov. 22, 2012

(54) LNA CIRCUIT FOR USE IN A LOW-COST RECEIVER CIRCUIT

(76) Inventor: Aslamali A. Rafi, Austin, TX (US)

(21) Appl. No.: 13/564,592

(22) Filed: Aug. 1, 2012

Related U.S. Application Data
(63) Continuation of application No. 12/824,927, filed on Jun. 28, 2010, now Pat. No. 8,242,844.

(51) Int. Cl. H03F 3/04

(52) U.S. Cl. 330/296

(57) ABSTRACT

A low-noise amplifier (LNA) includes an input terminal for receiving an input signal, an output terminal for providing an output signal related to the input signal. The LNA further includes a first transistor having a first source coupled to the input terminal through the first capacitor, a first gate configured to receive a first direct current (DC) bias signal, and a first drain coupled to the output terminal. The LNA also includes a second transistor having a second source coupled to the input terminal through the second capacitor, a second gate configured to receive a second DC bias signal, and a second drain coupled to the output terminal.

### CROSS REFERENCE TO RELATED APPLICATION(S)

This application is a continuation of and claims priority to U.S. application Ser. No. 12/824,927 filed on Jun. 28, 2010 and entitled “LNA Circuit for Use in a Low-Cost Receiver Circuit,” which is now U.S. Pat. No. 8,242,844, and which is incorporated herein by reference in its entirety.

### FIELD

The present disclosure is generally related to amplifiers, and more particularly, to low noise amplifiers (LNAs).

### BACKGROUND

Commercial television receivers and set-top boxes supporting various digital television standards require tuner circuitry capable of processing analog terrestrial, digital terrestrial, and cable broadcasts with low cost and small size. Such tuner circuitry may be configured to handle signals with broadband input frequencies ranging from 54 MHz to 880 MHz, and thus require a wideband LNA with sufficiently high linearity and a low noise figure well below 3 dB in order to obtain high sensitivity.

Narrow-band receivers, such as Code-Division Multiple Access (CDMA), Global System for Mobile Communications (GSM), short-range wireless receivers, and terrestrial digital multimedia broadcasting (T-DMB) receivers, are typically configured to tune to channels where the ratio of maximum frequency to minimum frequency is less than two. Unlike such narrow-band receivers, in a hybrid television tuner, the second and third-order input-referred intercept points (IIP2 and IIP3) of the LNA are important. The IIP2 and IIP3 of the LNA are important because, in the frequency band of reception (54 MHz to 880 MHz), there can be an interfering channel with a frequency that is half or a third of the desired frequency channel, which interfering channel, through second order or third order distortion, respectively, can land at the frequency of interest and corrupt the picture quality. Such second or third order distortion products are called HD2 (harmonic distortion 2) and HD3 (harmonic distortion 3), respectively.

Furthermore, in a cable TV environment, there can be several channels distributed over the frequency band of reception. These channels can inter-modulate amongst themselves through second order nonlinearities and corrupt the desired picture quality through composite second order distortion (CSO). Furthermore, in the presence of third order nonlinearities in a cable TV tuner, the TV channels can inter-modulate to produce a composite triple beat (CTB) which can further affect the desired picture quality. Hence, it is important that an LNA in a TV tuner has high IIP2 and IIP3. Therefore, since an LNA with a single-ended input and single-ended output typically has poor IIP2 performance, many tuners adopt a balun together with a fully differential LNA or a single-ended-to-differential amplifier as the first stage of the receiver circuit.

While fully differential LNAs can provide acceptable IIP2 performance over a wide range of frequencies, one of its main drawbacks is that passive transformers are typically required to convert the single-ended signal into a differential signal. Such transformers can be bulky; therefore, such transformers are generally implemented off-chip. Further, low-loss, external, passive transformers are typically expensive, adding to the overall cost of the system. Furthermore, the loss in these external transformers directly affects the Noise Figure (NF) of the TV tuner, which is one of the most important performance metrics of a TV tuner because the NF determines how small of a broadcast TV signal can be received at the antenna input.

A single-ended-to-differential amplifier represents a good configuration for integration and can provide moderate IIP2 performance. However, conventional single-ended-to-differential amplifiers typically have a relatively high NF. Unfortunately, the high NF degrades sensitivity of the tuner circuitry, making it difficult to use an LNA on the first stage in a wideband tuner.

### BRIEF DESCRIPTION OF THE DRAWINGS

FIG. 1 is a partial block and partial schematic diagram of a conventional, single-ended input, differential output, low-noise amplifier (LNA) with a balanced load.

FIG. 2 is a partial block and partial schematic diagram of a conventional, differential-input, differential output, LNA with a balanced load and a balun circuit.

FIG. 3 is a partial block and partial schematic diagram of a balunless LNA circuit configurable for use with a tuner circuit.

FIG. 4 is a block diagram of an embodiment of a device including the LNA circuit of FIG. 3.

FIG. 5 is a diagram of another embodiment of a device including the LNA circuit of FIG. 3 coupled to a passive mixer.

FIG. 6 is a diagram of still another embodiment of a device including the LNA of FIG. 3 coupled to a mixer through a resistive load.

In the following description, the use of the same reference numerals in different drawings indicates similar or identical items.

### DETAILED DESCRIPTION OF ILLUSTRATIVE EMBODIMENTS

An embodiment of a low-noise amplifier (LNA) is described below that is configured to achieve a second-order input-referred intercept point (IIP2) of greater than 50 dBm (dB milliwatts) while eliminating the balun and while reducing power consumption of the LNA by three-fourths as compared to a conventional LNA.

In the following discussion, the term “coupled” is used to refer to components that are directly connected or are joined or linked by indirect connection. It should understood that the illustrated embodiments are for illustrative purposes only, and that direct connections illustrated within the drawings may include elements and/or intervening components that are not shown.

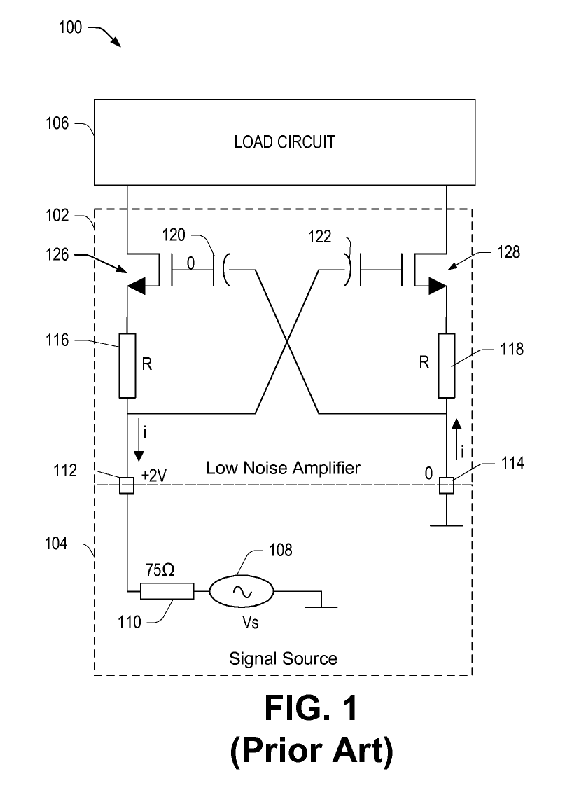

FIG. 1 is a partial block and partial schematic diagram of a conventional, single-input, differential-output low-noise amplifier (LNA) circuit 100 with a balanced load. LNA circuit 100 includes a LNA 102, which is coupled to a signal source 104 and to a load circuit 106. Load circuit 106 can be a tuner, switches of a mixer, or other circuitry. Signal source 104 can be an antenna or other circuitry for receiving a broadband signal. Signal source 104 models an antenna as a voltage source 108 that applies a signal to a resistance 110, such as a 75 Ohm resistor. The resistor 110 is coupled to a pin 112 of LNA 102.

LNA 102 includes pin 112 and a second pin 114, which is coupled to ground. LNA 102 further includes resistors 116 and 118, transistors 126 and 128, and capacitors 120 and 122. Resistor 116 has a first terminal coupled to pin 112 and a second terminal coupled to a source of a transistor 126, which is an n-channel metal oxide semiconductor field effect transistor (NMOSFET). Transistor 126 includes a gate coupled to pin 114 through capacitor 114, and a drain coupled to balanced load circuit 106. Resistor 118 includes a first terminal coupled to pin 114 and a second terminal coupled to a source of transistor 128. Transistor 128 further includes a gate coupled to pin 112 through capacitor 122 and a drain coupled to balanced load circuit 106. In this example, transistors 126 and 128, capacitors 120 and 122, and resistors 116 and 118 are substantially matched, providing a balanced circuit.

In operation, signal source 104 provides radio frequency (RF) signals to pin 112, and pin 114 is coupled to ground. The RF input at pin 112 is applied to transistor 126 and resistor 116 and is provided to the gate of transistor 128. Small signal (high frequency) current (i) flows from drain to source through transistor 126 and from source to drain through transistor 128. For a given voltage signal source (Vs), the current (i) is the same through both transistors 126 and 128. Thus, a differential output current is produced from a single ended voltage input. As used herein, the term “radio frequency” refers to a signal having a frequency within a range from approximately 3 kHz to hundreds of Gigahertz. High frequency signals or small signals refer to AC components or RF components of the signal.

Analysis indicates that an optimal noise figure is obtained according to the following equation:

$$50 Ω \approx R + \frac{1}{gm} \qquad ( 1 )$$

In Equation 1, the variable (R) represents the resistance of each of the resistors 116 and 118 and the variable (gm) represents the transconductance of each of transistors 126 and 128. In this instance, an optimized noise figure of LNA 102 is as high as 6 dB. However, the noise figure of 6 dB is not acceptable for terrestrial applications. Further, the IIP2 was only 40 dBm (the power ratio referenced to one milliwatt), which is insufficient for cable applications for which 50 dBm is a typical threshold. Unfortunately, the common source stage represented by transistor 128 contributes significant noise to the signal, adversely affecting the noise figure (NF) and sensitivity of the system while giving insufficient IIP2 performance.

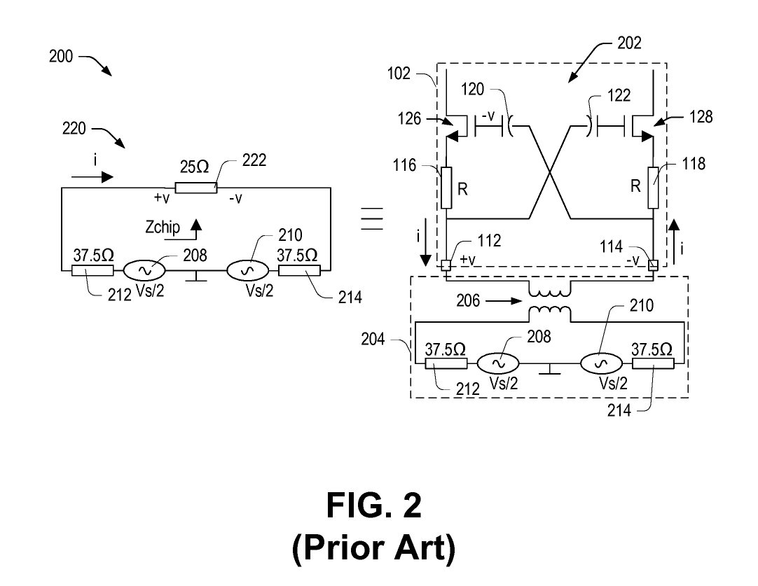

While a single-ended input avoids the use of external and bulky passive transformers, due to the relatively high noise figure, it is difficult to place LNA 102 on the first stage in a wideband tuner due to the resulting sensitivity degradation. Conventionally, a balun circuit, such as an external transformer, is used to convert the single-ended input into a differential input through electromagnetic coupling. An example of an LNA circuit that uses a balun circuit is described below with respect to FIG. 2.

FIG. 2 is a partial block and partial schematic diagram of a conventional, dual-input LNA circuit 200, including the LNA 102 of FIG. 1 and including a balun circuit 206. In this example, signal source 104 is replaced with a signal source 204 that includes balun circuit 206 (depicted as a simple transformer). Further, the voltage signal source (Vs) 108 depicted in FIG. 1 is divided into input sources 208 and 210, each of which are approximately half of the voltage signal source (Vs), i.e., Vs/2. Signal source 204 includes resistors 212 and 214, each of which is approximately 37.5Ω or half of the resistance of resistor 110 in FIG. 1.

In operation, signal source 204 divides the balanced, single-ended input signal (which may be received from an antenna or other signal source) into an unbalanced signal using passive transformer 206 as a balun, and provides the resulting signals to LNA 102 at pins 112 and 114. The small signal voltages appear across transistor 126 and 128, causing small signal current (i) to flow from drain to source through transistor 126 and from source to drain through transistor 128, as shown.

Diagram 200 further includes an equivalent circuit 220 illustrating the effective impedance 222 of LNA circuit 202. In this instance, the effective impedance of LNA 102 is determined from the resistance of resistors 116 and 128 plus one over the transconductance (gm) of transistors 126 and 128, which is approximately 25Ω. The effective impedance is defined by Equation 2 below.

$$25 Ω \approx R + \frac{1}{gm} \qquad ( 2 )$$

For a given voltage signal source (Vs), the small signal current (i) flowing in both networks is the same. Further, the voltage across the effective 25Ω resistance is approximately the same as the voltage across the transconductor.

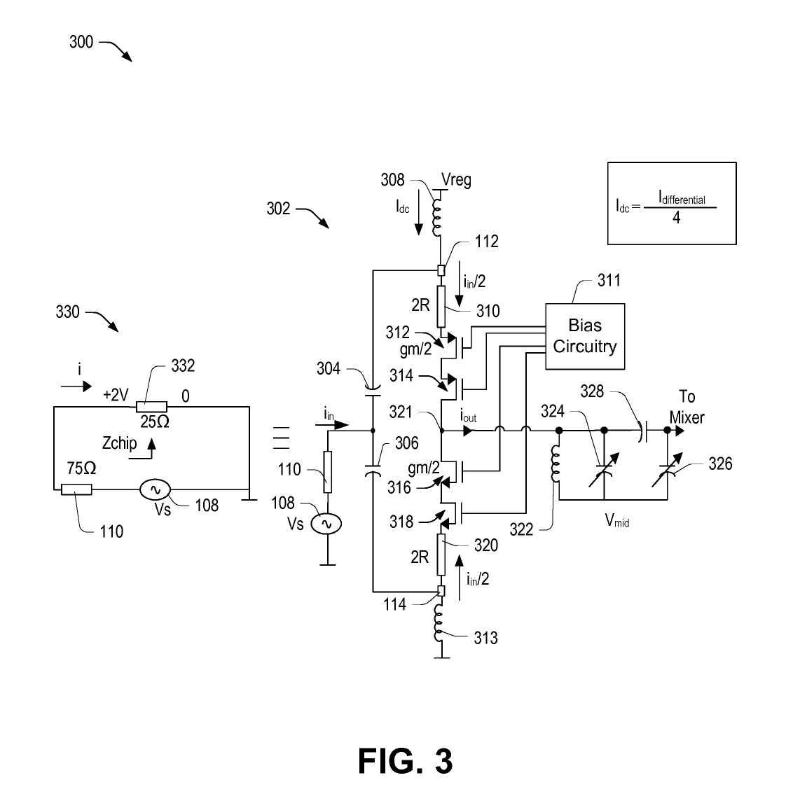

In the illustrated embodiment of FIG. 2, the noise figure is dominated by the 25Ω impedance. While the fully differential LNA illustrated in FIG. 2 can provide excellent IIP2 performance over a wide frequency band, a drawback of circuit 200 is that the passive transformer 206 is required. Such a passive transformer is typically too bulky to be integrated on the chip, and its insertion loss degrades the receiver's noise figure and its sensitivity. To avoid such degradation, low-loss and expensive external transformers are used, increasing both the size and expense of the circuitry. As discussed below with respect to FIGS. 3-8, it is possible to provide a single-input, balunless LNA that obtains a noise figure, IIP2, IIP3, gain, and sensitivity that is sufficient for use with terrestrial applications, with reduced power consumption and reduced cost.

FIG. 3 is a partial block and partial schematic diagram of an embodiment of a circuit 300 including a single-input, balunless LNA 302 configurable for use with a tuner circuit. Circuit 300 includes a signal source, such as an antenna, a broadband connection, or other signal source. In this instance, the signal source is represented by voltage signal source (Vs) 112, which provides RF signals to LNA 302. The voltage signal source (Vs) 112 is capacitively coupled to inputs 112 and 114 through capacitors 304 and 306, respectively, which operate to block direct current and low frequency signals.

As compared to circuit 200 in FIG. 2, the cross-coupling capacitors 120 and 122 have been removed, and half of the transconductor is folded to p-channel metal oxide semiconductor (PMOS) transistors 312 and 314. LNA 302 includes a direct current (DC) current source, represented by inductor 308 coupled to a regulated supply voltage (Vreg). Inductor 308 is coupled to pin 112 for injecting a DC current (I_{dc}) into the pin 112. LNA 302 further includes a resistor 310 having a first terminal coupled to pin 112 and a second terminal coupled to a source of transistor 312, which includes a gate coupled to bias circuitry 311, and a drain coupled to a source of transistor 314. Transistor 314 further includes a gate coupled to bias circuitry 311 and a drain coupled to an output node 321. The gates of transistors 312 and 314 appropriately biased by bias circuitry 311 to permit the DC current (I_{dc}) to flow through transistors 312 and 314. From a RF signal point of view, the gates of transistors 312 and 314 can be thought of as being at ground.

LNA 302 further includes an NMOS transistor 316 including a drain coupled to output node 321, a gate coupled to bias circuitry 311, and a source coupled to a drain of NMOS transistor 318, which also includes a gate coupled to bias circuitry 311 and a source coupled to pin 114 through resistor 320. A second current source, represented by inductor 313, couples pin 114 to a supply terminal, which may be negative supply terminal or which may include other circuitry. Capacitor 306 blocks DC current flow to voltage signal source (Vs) 108, forcing the DC current (I_{dc}) into inductor 313.

In the illustrated embodiments, details of bias circuitry 311 are omitted for the sake of simplicity. However, any biasing circuitry, including operational amplifiers, control circuits, voltage divider circuits, or other appropriate circuitry can be used to bias transistors 312, 314, 316 and 318 sufficiently to allow current flow through the transistors.

In the illustrated embodiment, output node 321 is coupled to a mixer. The inductor 322 and variable capacitor 324 form a tunable band-pass LC filter, also known as a tracking filter. Fixed capacitor 328 and variable capacitor 326 form a capacitive attenuator network that is used to reduce the gain prior to the mixer in the presence of strong signals.

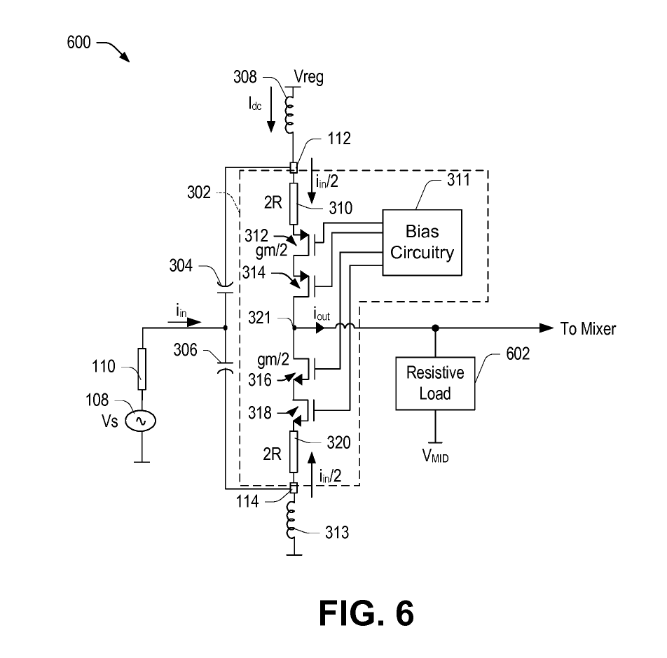

Though in the embodiment shown in FIG. 3, the LNA transconductor comprised of resistors 310 and 320 and transistors 312, 314, 316, and 318 is shown coupled to a tracking filter and capacitive attenuator comprised of inductor 322 and capacitors 324, 326 and 328, other embodiments are also possible. For example, the LNA transcondutor could be coupled to switches of a passive mixer (as depicted in FIG. 5) or to a simple resistive load (as illustrated in FIG. 6).

In operation, the gates of PMOS transistors 312 and 314 and NMOS transistors 316 and 318 are biased to permit DC current (I_{dc}) to flow. However, the gates of transistors 312, 314, 316, and 318 receive no small signal currents. The RF input signal (iᵢₙ) produced by voltage signal source (Vs) 108 flows through resistor 110 and divides substantially evenly to flow into pins 112 and 114. The inductors 313 and 308 operate as open circuits with respect to the small signal inputs (iᵢₙ/2), forcing the small signal inputs (iᵢₙ/2) to flow through PMOS transistors 312 and 314 and through NMOS transistors 316 and 318 to output node 321, which carries the small signal output current (iₒᵤₜ).

In the illustrated embodiment, NMOS transistors 316 and 318 and PMOS transistors 312 and 314 in parallel. Thus, the impedance (Zchip) of the LNA 302 (as seen looking into pins 112 and 114) is determined according to the following equation:

$$Zchip = ( 2 R + \frac{2}{gm} ) \vert \vert ( 2 R + \frac{2}{gm} ) \qquad ( 3 )$$

In Equation 3, the resistance (2R) is twice the resistance (R) of the resistors 116 and 118 in circuits 100 and 200 in FIGS. 1 and 2. The variable (gm) represents the transconductance of transistors 312 and 316. Equation 3 can be simplified as shown in Equation 4 below:

$$Zchip = R + \frac{1}{gm} = 25 Ω \qquad ( 4 )$$

The equivalent circuit 330 depicts the input resistance 110 and voltage signal source (Vs) 108 and illustrates the input impedance (Zchip) of the LNA 302, which is represented by resistor 332. Thus, the simplified circuit 302 has the same equivalent circuit as the differential circuit 200 in FIG. 2.

In the illustrated embodiment, the noise figure is better than the differential case. For the differential case (as depicted in FIG. 1), the NF of the trasnconductor can be approximated according to Equation 5 below:

$${NF}_{102} = 10 * log ( 1 + \frac{Zchip}{2 * 75} ) \qquad ( 5 )$$

For an impedance (Zchip) equal to about 25 ohms, the NF is about 0.7 dB. However, the off-chip balun can have a loss of about 1.3 dB, further degrading the total NF to about 2 dB. In contrast, the single ended transconductor of FIG. 3 has an NF that can be approximated according to the Equation 6 below:

$${NF}_{302} = 10 * log ( 1 + \frac{Zchip}{75} ) \qquad ( 6 )$$

For the same impedance (Zchip) of 25 ohms, the NF of LNA 302 is 1.25 dB. Since an off-chip balun is not used, the total NF is also 1.25 dB, which is better than the 2 dB NF of the differential case with the balun. Furthermore, for a given voltage signal source (Vs) 108, the small signal current (i) flowing into the LNA remains the same as in the differential case, and hence gain is also the same.

For the single-ended CMOS transconductor (with NMOS and PMOS devices in parallel) as shown in FIG. 3, LNA 302 is similar to the LNA 102 in FIG. 1. Thus, the third-order input-referred intercept point (IIP3) is substantially the same as the differential structure depicted in FIG. 2. The IIP3 of LNA 302 is described below with respect to Equation 7.

$$IIP 3 ∝ Von \cdot {( 1 + gmR )}^{\frac{3}{2}} \qquad ( 7 )$$

Further, the second-order input-referred intercept point (IIP2) is also improved, as compared to the single-end input LNA 102 in FIG. 1. The IIP2 is improved by using conventional push-pull complementary stages. Second order distortion is characterized by asymmetric positive and negative half cycles. During the positive half cycle, NMOS transistors 316 and 318 have a small “on” voltage (Von), while PMOS has a larger “on” voltage (Von). During the negative half cycle, the opposite is true. If NMOS and PMOS transistors 312 and 318 match, then the second order distortion cancels. However, process variations that cause NMOS transistor 318 to be different from PMOS transistor 312 can cause the IIP2 to change.

The “on” voltages of PMOS and NMOS transistors 312, 314, 316, and 318 are opposite, balancing out. Further, using source degeneration resistors 310 and 320 desensitizes the “effective” on voltage (voltage across resistors plus “on” voltage of transistors) variations across process corners.

However, testing has shown that LNA 302 has a satisfactory IIP2 across process corners, which exceeds 50 dBm. Table 1 below depicts the IIP2 of one specific example of LNA 302 where the PMOS transistors 312 and 314 had width/length ratios that were 2.00 times that of NMOS transistors 316 and 318.

TABLE 1
IIP2 of LNA 302 across Process Corners.

| PROCESS CORNER | IIP2 (dBm) |
|---|---|
| Typical-Typical (TT) | 54 |
| Slow NMOS Fast PMOS (SNFP) | 61 |
| Fast NMOS Slow PMOS (FNSP) | 51 |
| Fast NMOS Fast PMOS (FNFP) | 56 |
| Slow NMOS Slow PMOS (SNSP) | 53 |

As shown in Table 2, LNA 302 exceeds 50 dBm at all process corners. Further, trimming devices can be added, which change the ratio PMOS W/L to NMOS W/L, to fine tune performance. However, even at the 2.00× difference between the PMOS and NMOS devices, performance falls within the acceptable range.

Further, the DC current (I_{dc}) is approximately equal to one-fourth of a differential current (I_{differential}), representing a 4× current savings over a conventional LNA. Referring to LNA 102 in FIG. 2, each NMOS transistor 126 and 128 has a transconductance of gm and each single-ended brand drew a DC current of I_{diff}/2. For the CMOS LNA 302, the PMOS and NMOS transistors 312, 314, 316, and 318, each transistor 312, 314, 316, and 318 has a transconductance of gm/2 while sharing the same DC current. This implies that the current drawn is one-quarter of the differential current (I_{diff}) as follows:

$$\frac{1}{2} * ( \frac{{I}_{diff}}{2} ) = \frac{{I}_{diff}}{4} \qquad ( 8 )$$

The resulting current represents a 4× current reduction as compared to the DC current flowing within LNA 102 in FIG. 2, for example. Thus, LNA 302 has noise figure, IIP2, IIP3, and gain parameters that satisfy terrestrial TV signal processing requirements, while using less DC current.

With a single-ended load of 440 Ohms, which matches the differential load of some LNAs with a balun, Table 2 below represents a simulation performance summary and comparison of LNA 302 with LNA 102 in FIG. 2, for example, with a corresponding 440 Ohm load, transconductance of NMOS and PMOS being 40 mS each and resistors 310, 320 in FIG. 3 each being 25 ohms, the following performance is obtained.

TABLE 2
LNA 302 versus LNA 102 Performance Comparisons.

| | CMOS LNA 302 | | LNA 102 | |
|---|---|---|---|---|
| | Without Balun | | with Balun | |
| S11 (Input Reflection | ~−7 | dB | ~−6 | dB |
| Parameter) | | | | |
| Noise Figure (@ 400 MHz) | 2.6 | dB | 3.5 | dB |
| Gain | 18 | dB | 18 | dB |
| IIP2 (Typical-Typical) | 54 | dBm | 55 | dBm |
| IIP3 (Out of Band) | 26 | dBm | 26 | dBm |
| DC Power | 9 | mA | 40 | mA |

As indicated in Table 2, the CMOS LNA 302 without the balun substantially matches performance of the LNA 102 with the balun. The NF of LNA 302 is better than that of LNA 102, while IIP2, IIP3 and Gain numbers are comparable between the two. Also, DC current drawn by LNA 302 is 75% less than that drawn by LNA 102. Performance of the LNA 302 across process corners can be adjusted for a particular implementation. In particular, at design time, the width/length (W/L) ratio of PMOS 312 and the W/L of NMOS 318 can be designed to optimize the IIP2 performance across process corners.

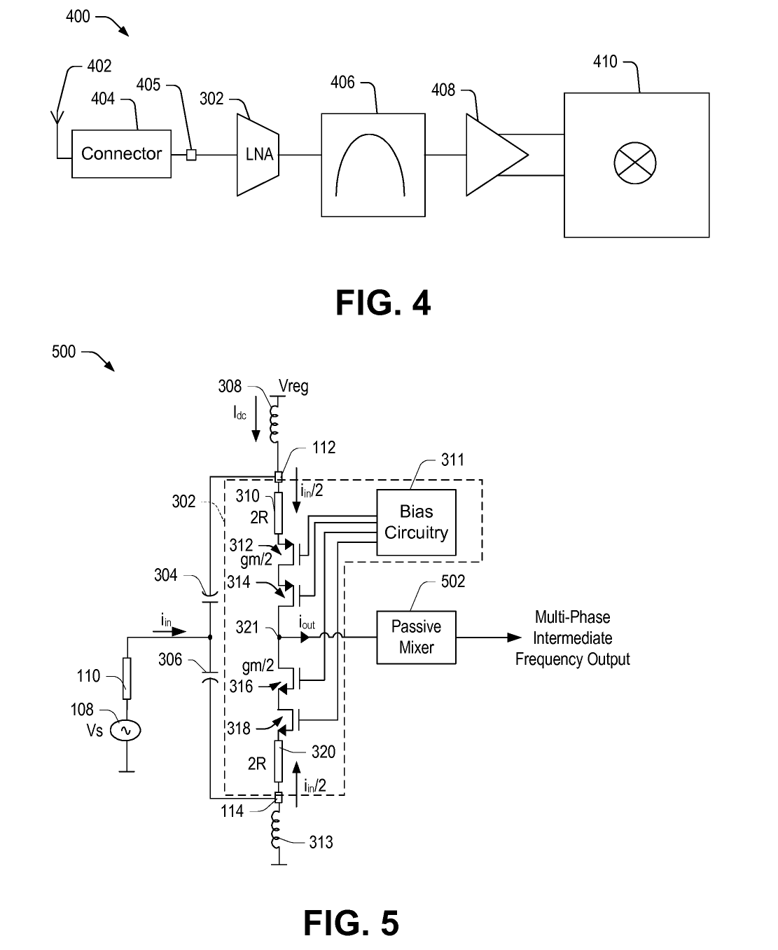

FIG. 4 is a block diagram of a device 400 including the LNA 302 of FIG. 3. Device 400 further includes an antenna 402, connector 404, pin 405, and capacitive filter and capacitive attenuator 406, which includes an output coupled to a single input to differential output converter 408, which is coupled to a double balanced harmonic rejection mixer (HRM) 410.

In this embodiment, the CMOS LNA 302 obtains a noise figure of 2.6 dB, a gain of 18 dB, and IIP2 of 50 dBm, an IIP3 of 25 dBm, and a DC current of approximately 10 mA. The single-ended capacitive filter and capacitive attenuator 406 provides a single-ended transfer function that provides the same load as a differential load. The single input to differential output converter 408 obtains a noise figure of 9 dB, a gain of 0 dB, an IIP3 of 15 dBm, and a DC current of approximately 15 mA. HRM 410 obtains a noise figure of 12 dB, a gain of 19 dB, and an IIP3 of 12 dBm. In this particular embodiment, the 30 mA current saved by using LNA 302 as compared to LNA 102 can be used to provide power to other circuitry. For example, part of the saved 30 mA can be used in the single ended to differential output converter 408 to supply the 15 mA.

It should be understood that the embodiments illustrated in FIGS. 1-4 are illustrative only. In the above-examples, the gains, decibel levels, and currents were provided for illustrative purposes. Such values may be appropriate for particular implementations and/or may vary across different circuit implementations.

FIG. 5 is a diagram of another embodiment of a device 500 including the LNA circuit 302 of FIG. 3 coupled to a passive mixer 502, which is configured to receive the output current (iout) and to produce a multi-phase intermediate frequency (IF) output signal, which can be provided to other circuitry, such as a filter, an IF amplifier, a processor, and/or other circuitry configured to process the IF output signal.

While the LNA 302 of FIG. 3 is coupled to a mixer through an LC network and the LNA 302 of FIG. 5 is coupled to a passive mixer without intervening circuitry, other embodiments may include resistive loads or other circuitry between the LNA 302 and the mixer. An example of an embodiment of a device is described below with respect to FIG. 6 that includes LNA 302 coupled to a resistive load and a mixer.

FIG. 6 is a diagram of still another embodiment of a device 600 including the LNA 302 of FIG. 3 coupled to a mixer through a resistive load 602. In this example, the resistive load includes a first terminal coupled to output node 321 and a second terminal coupled to a voltage source, such as a VMID (a buffered voltage at approximately a midpoint between a power supply rail and ground).

In general, LNA 302 may be used in a variety of devices to provide low-noise amplification with reduced power consumption (as compared to the differential LNA 102 of FIG. 1). Further, while LNA 302 has been depicted with input pins 112 and 114 for receiving the input signals from a signal source, such as antenna 402, it should be understood that pins 112 and 114 may be eliminated and that a single pin or input terminal may be used to provide the input signal to capacitors 304 and 306, which may be on-chip capacitors.

In conjunction with the circuit 300 depicted in FIG. 3 and the devices 400, 500, and 600 depicted in FIGS. 4-6, respectively, together with the tables 1 and 2, a highly linear single-ended, balunless LNA 302 is presented that achieves an IIP3 of 25 dBm, an IIP2 of 50 dBm (over process corners), and a noise figure of 2.6 dB while consuming only 10 mA of current. In this instance, the reflection loss achieved is about −6 dB. The LNA lowers costs by eliminating the balun while adding only one off-chip inductor and one capacitor to the bill of materials. The current savings is approximately 30 mA, which current may be used to provide power to other circuitry, thereby conserving overall power consumption.

Although the present invention has been described with reference to preferred embodiments, workers skilled in the art will recognize that changes may be made in form and detail without departing from the scope of the invention.

What is claimed is:

1. A low-noise amplifier (LNA) comprising:
an input node configured to receive an input signal;
an output node;
a first capacitor coupled between the input node and a first node;
a second capacitor coupled between the input node and a second node;
a first transistor including a first terminal coupled to the first node, a control terminal configured to receive a first direct current (DC) bias signal, and a second terminal coupled to the output node; and
a second transistor including a first terminal coupled to the second node, a control terminal configured to receive a second DC bias signal, and a second terminal coupled to the output node.

2. The LNA of claim 1, wherein:
the first capacitor includes a first terminal coupled to the input node and a second terminal coupled to the first node;
the second capacitor includes a first terminal coupled to the input node and a second terminal coupled to the second node; and
the first terminals of the first and second capacitors are coupled to each other.

3. The LNA of claim 1, further comprising:
a first inductor having a first terminal coupled to the first node and a second terminal coupled to a first DC supply node; and
a second inductor including a first terminal coupled to the second node and a second terminal coupled to a second DC supply node.

4. The LNA of claim 1, wherein the first transistor comprises a p-channel metal oxide semiconductor field effect transistor (MOSFET) and the second transistor comprises an n-channel MOSFET.

5. The LNA of claim 4, wherein the first transistor and the second transistor are substantially matched and operate as push-pull complementary stages that substantially cancel second-order distortion.

6. The LNA of claim 4, further comprising:
a first resistor including a first terminal coupled to the first node and a second terminal coupled to the first terminal of the first transistor; and
a second resistor including a first terminal coupled to the second node and a second terminal coupled to the first terminal of the second transistor.

7. The LNA of claim 4, wherein the first resistor and the second resistor operate to desensitize on voltage variations between the first and second transistors across process corners.

8. A low-noise amplifier (LNA) comprising:
an input node configured to receive an input signal;
an output node;
a first capacitor including a first current electrode coupled to the input node and a second current electrode coupled to a first node;
a second capacitor including a first current electrode coupled to the input node and a second current electrode coupled to a second node;
a first transistor circuit including a first terminal coupled to the first node, a control terminal configured to receive a first direct current (DC) bias signal, and a second terminal coupled to the output node; and
a second transistor circuit including a first terminal coupled to the second node, a control terminal configured to receive a second DC bias signal, and a second terminal coupled to the output node.

9. The LNA of claim 8, wherein the first transistor circuit comprises a p-channel metal oxide semiconductor field effect transistor (PMOSFET) circuit and the second transistor comprises an n-channel metal oxide semiconductor field effect transistor (NMOSFET) circuit.

10. The LNA circuit of claim 9, wherein the first transistor circuit comprises:
a first PMOSFET including a source forming the first terminal of the first transistor circuit, the source coupled to the first node, the first PMOSFET further including a gate and a drain; and
a second PMOSFET including a source coupled to the drain of the first PMOSFET, a gate, and a drain coupled to the output node.

11. The LNA circuit of claim 10, wherein the second transistor circuit comprises:
a first NMOSFET including a source forming the first terminal of the second transistor circuit, the source coupled to the first node, the first NMOSFET further including a gate and a drain; and
a second NMOSFET including a source coupled to the drain of the first NMOSFET, a gate, and a drain coupled to the output node.

12. The LNA circuit of claim 12, further comprising a bias circuit configured to selectively provide the first DC bias signal to the gates of the first and second PMOSFETs and to selectively provide the second DC bias signal to the gates of the first and second NMOSFETs.

13. The LNA circuit of claim 8, wherein the first and second transistor circuits have substantially equal on voltages and operate as push-pull complementary stages that substantially cancel second-order distortion.

14. The LNA circuit of claim 13, further comprising:
a first resistor including a first terminal coupled to the first node and a second terminal coupled to the first terminal of the first transistor; and
a second resistor including a first terminal coupled to the second node and a second terminal coupled to the first terminal of the second transistor; and
wherein the first and second resistors provide source degeneration for the first and second transistor circuits to reduce sensitivity to variations in the on voltages across process corners

15. A low-noise amplifier (LNA) comprising:
an input node configured to receive an input signal;
an output node;
a first capacitor coupled between the input node and a first node;
a second capacitor coupled between the input node and a second node;
a first transistor circuit including a first terminal coupled to the first node, a control terminal configured to receive a first direct current (DC) bias signal, and a second terminal coupled to the output node; and
a second transistor circuit including a first terminal coupled to the second node, a control terminal configured to receive a second DC bias signal, and a second terminal coupled to the output node; and
wherein the first and second transistors operate as push-pull complementary stages that substantially cancel second-order distortion.

16. The LNA of claim 15, further comprising:
a first resistor including a first terminal coupled to the first node and a second terminal coupled to the first terminal of the first transistor; and
a second resistor including a first terminal coupled to the second node and a second terminal coupled to the first terminal of the second transistor.

17. The LNA of claim 16, wherein the first resistor and the second resistor operate to desensitize variations in on voltages between the first and second transistors across process corners.

18. The LNA of claim 15, wherein:
the first transistor circuit comprises:
a first p-channel metal oxide semiconductor field effect transistor (PMOSFET) including a source forming the first terminal of the first transistor circuit, the source coupled to the first node, the first PMOSFET further including a gate and a drain; and
a second PMOSFET including a source coupled to the drain of the first PMOSFET, a gate, and a drain coupled to the output node; and
the second transistor circuit comprises:
a first n-channel metal oxide semiconductor field effect transistor (NMOSFET) including a source forming the first terminal of the second transistor circuit, the source coupled to the first node, the first NMOSFET further including a gate and a drain; and
a second NMOSFET including a source coupled to the drain of the first NMOSFET, a gate, and a drain coupled to the output node.

19. The LNA of claim 18, further comprising a bias circuit coupled to the gates of the first and second PMOSFETs and to the gates of the first and second NMOSFETs.

20. The LNA of claim 15, further comprising:
a first inductor having a first terminal coupled to the first node and a second terminal coupled to a first DC supply node; and
a second inductor including a first terminal coupled to the second node and a second terminal coupled to a second DC supply node.
